(19) United States
(12) Patent Application Publication
(10) Pub. No.: US 2017/0084614 A1
(43) Pub. Date: Mar. 23, 2017

(54) MEMORY CELL WITH OXIDE SEMICONDUCTOR FIELD EFFECT TRANSISTOR DEVICE INTEGRATED THEREIN

(71) Applicant: UNITED MICROELECTRONICS CORP., Hsin-Chu City (TW)

(72) Inventors: Shao-Hui Wu, Singapore (SG); ZHIBIAO ZHOU, Singapore (SG); HAI BIAO YAO, Singapore (SG); Chi-Fa Ku, Kaohsiung City (TW); Chen-Bin Lin, Taipei City (TW)

(21) Appl. No.: 14/856,565

(22) Filed: Sep. 17, 2015

(51) Int. Cl. H01L 27/108; H01L 29/786

(52) U.S. Cl. CPC H01L 27/10832; H01L 29/7869

(57) ABSTRACT

A memory cell includes a substrate, a deep trench (DT) capacitor formed in the substrate, at least an insulting layer formed on the substrate, and an oxide semiconductor field effect transistor (OS FET) device formed on the insulating layer. And more important, the OS FET device is electrically connected to the DT capacitor.

### BACKGROUND OF THE INVENTION

1. Field of the Invention

The present invention relates to a memory cell, and more particularly, to a memory cell with an oxide semiconductor field effect transistor (hereinafter abbreviated as OS FET) device integrated therein.

2. Description of the Prior Art

As the complexity and power of computing systems increase, the amount of memory required for systems has also increased. This has resulted in the drive for semiconductor memory devices of increased storage capacity. At the same time, the desire for more efficient manufacturing and more compact electronic devices, has led to the competing interest of shrinking semiconductor memory devices to as small a size as possible.

### SUMMARY OF THE INVENTION

According to an aspect of the present invention, a memory cell is provided. The memory cell includes a substrate, a deep trench (hereinafter abbreviated as DT) capacitor formed in the substrate, at least an insulting layer formed on the substrate, and an OS FET device formed on the insulating layer. More important, the OS FET device is electrically connected to the DT capacitor.

According to the memory cell provided by the present invention, the DT capacitor is formed in the substrate before forming the OS FET device, therefore a depth of the DT capacitor can be increased to several decades to several hundreds micrometers (μm). That is, a higher capacitance can be achieved without increasing the memory cell size according to the present invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a circuit diagram of a DOSRAM cell provided by a first preferred embodiment of the present invention.

FIG. 2 is a schematic drawing illustrating the DOSRAM cell provided by the first preferred embodiment.

FIG. 3 is a circuit diagram of a NOSRAM cell provided by a second preferred embodiment of the present invention.

FIG. 4 is a schematic drawing illustrating the NOSRAM cell provided by the second preferred embodiment.

### DETAILED DESCRIPTION

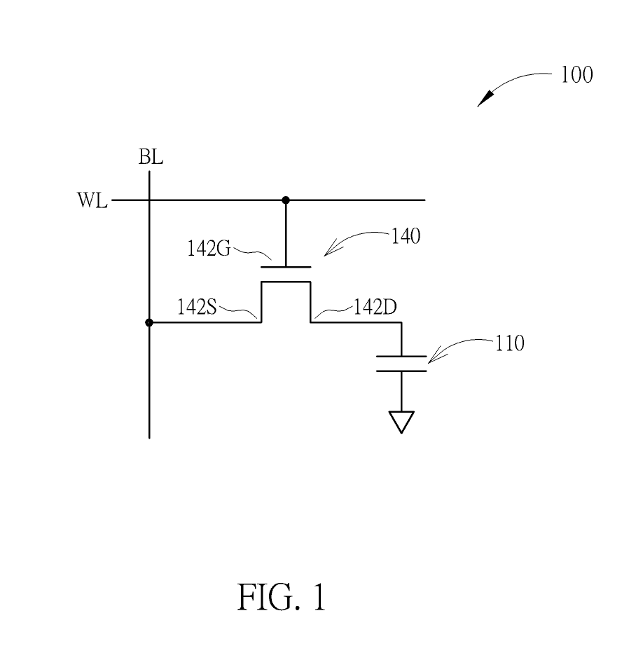

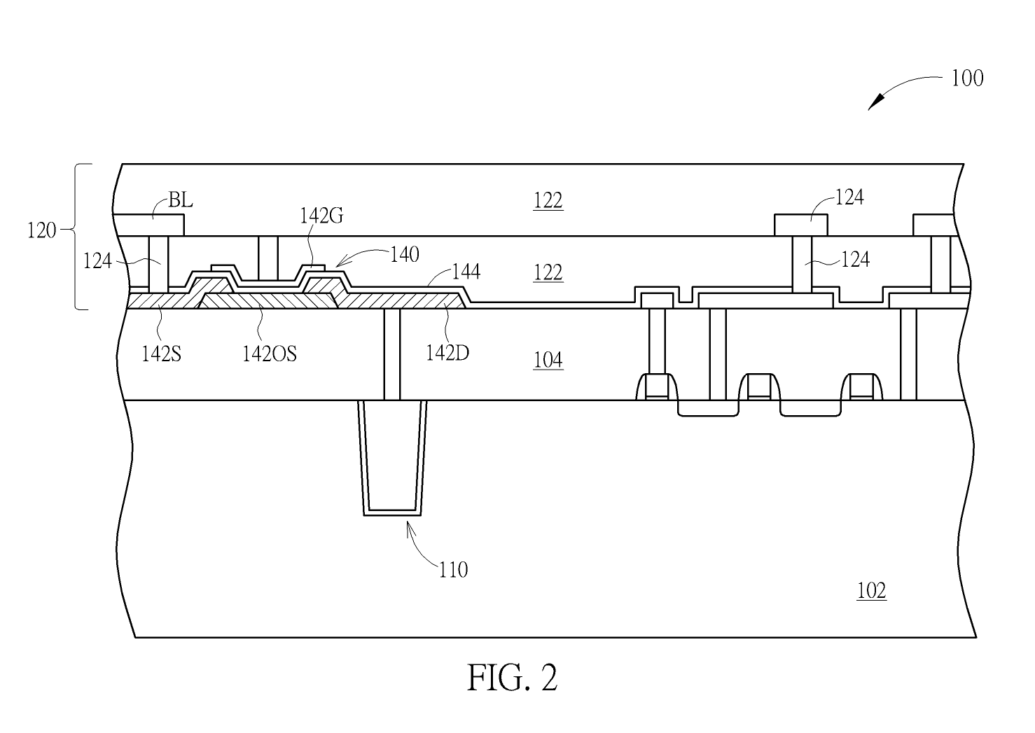

According to a first preferred embodiment of the present invention, a dynamic oxide semiconductor random access memory (hereinafter abbreviated as DOSRAM) cell is provided. It should be noted that since an OS FET device renders excellent electric characteristics of an extremely low off-state current, the OS FET device is integrated in the DRAM. Hence the DRAM cell with the OS FET integrated therein is referred to as a DOSRAM cell. Please refer to FIG. 1 and FIG. 2, FIG. 1 is a circuit diagram of a DOSRAM cell provided by a first preferred embodiment of the present invention and FIG. 2 is a schematic drawing illustrating the DOSRAM cell provided by the first preferred embodiment.

As shown in FIG. 2. The DOSRAM cell 100 provided by the first preferred embodiment includes a substrate 102 and a DT capacitor 110 formed therein. The “substrate” 102 includes a semiconductor substrate, a semiconductor epitaxial layer deposited or otherwise formed on a semiconductor substrate and/or any other type of semiconductor body, and all such structures are contemplated as falling within the scope of the present invention. For example but not limited to, the semiconductor substrate may include a semiconductor wafer (e.g., silicon, SiGe, or an silicon-on-insulator (SOI) wafer) or one or more die on a wafer, and any epitaxial layers or other type semiconductor layers formed thereon or associated therewith. A portion or entire semiconductor substrate may be amorphous, polycrystalline, or single-crystalline. Additionally, the semiconductor substrate may be doped, undoped or contain doped regions and undoped regions therein. Also, the semiconductor substrate may contain regions with strain stress and regions without strain therein, or contain regions of tensile strain stress and compressive strain stress.

Please still refer to FIG. 2. The DT capacitor 110 of the DOSRAM 100 can be formed by the following steps: An etching process is performed to form a deep trench (not shown) into the substrate 102. The deep trench may have a depth from several decades to several hundreds micrometers. It should be easily understood that the deep trench is much deep than its wide. Next, a bottom electrode, a dielectric layer, and a top electrode are sequentially formed in the deep trench and thus the DT capacitor 110 is obtained as shown in FIG. 2. In the preferred embodiment, the DT capacitor 110 is preferably a deep trench metal-insulator-metal (herein after abbreviated as DT MIM) capacitor, but not limited to this. The DT capacitor 110 is generally formed, as follows: Beginning with a deep trench (not shown) is formed, extending into the substrate 102, from a top (as viewed) surface thereof. The deep trench is lined with a metal material that serves as a bottom electrode (not shown) of the DT capacitor 110. A dielectric layer (not shown) is then formed to line the bottom electrode in the deep trench plate, and followed by filling up the deep trench with a metal material that serves as a top electrode of the DT capacitor 110.

Please still refer to FIG. 2. Next, a plurality of active and/or passive devices (not shown) can be fabricated in and/or on the substrate 102 by front-end-of-line (hereinafter abbreviated as FEOL) processes. The active and/or passive devices construct integrated circuit(s) required for the memory. Device designs for the above mentioned active/passive devices and the details of the FEOL processes are familiar to a person having ordinary skill in the art, therefore those details are all omitted in the interest of brevity. Thereafter, at least an insulating layer 104 such as an interlayer dielectric (hereinafter abbreviated as ILD) layer 104 is formed to cover the devices and the DT capacitor 110. Next, a back-end-of-line (hereinafter abbreviated as BEOL) interconnection structure 120 is formed on the substrate 102. The BEOL interconnection structure 120 interconnects the active/passive devices of the integrated circuit (s) and may provide circuit-to-circuit connections, or may establish contacts with input and output terminals. As shown in FIG. 2, the BEOL interconnection structure 120 includes a plurality of dielectric layers 122 such as inter-metal dielectric (hereinafter abbreviated as IMD) layers and a plurality of metal layers 124 (including wires and vias) formed in the dielectric layers 122. The dielectric layers 122 include, for example but not limited to, silicon oxide and the metal layers 124 include, also for example but not limited to, aluminum (Al) or copper (Cu). It is well-known to those skilled in the art that the BEOL interconnection structure 120 is formed by steps of forming one dielectric layer 122, forming recesses (not shown) in the dielectric layer 122, and filling up the recesses with metal material such as Al or Cu to form the metal layers 124. These abovementioned steps can be repeated any number of times to form the stacked structure of the BEOL interconnection structure 120. As shown in FIG. 2, the ILD layer 104 and the dielectric layer 122 all cover the DT capacitor 110.

More important, the DOSRAM 100 provided by the first preferred embodiment includes an OS FET device 140 formed in the BEOL interconnection structure 120. That is, the OS FET device 140 is formed on the insulating layer 104. The OS FET device 140 includes an oxide semiconductor (hereinafter abbreviated as OS) layer 1420S, a gate electrode 142G, a source electrode 142S, a drain electrode 142D, and a dielectric layer 144 isolating the gate electrode 142G from the OS layer 1420S, the source electrode 142S and the drain electrode 142D. The OS layer 1420S includes, for example but not limited to, indium oxide, tin oxide, zinc oxide, two-component metal oxide such as In—Zn-based oxide, Sn—Zn-based oxide, Al—Zn-based oxide, Zn—Mg-based oxide, Sn—Mg-based oxide, In—Mg-based oxide, or In—Ga-based oxide, three-component metal oxide such as In—Ga—Zn-based oxide (also referred to as IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, or In—Lu—Zn-based oxide, four-component metal oxide such as In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, or In—Hf—Al—Zn-based oxide. Furthermore, the OS layer 1420S can include a c-axis aligned crystalline oxide semiconductor (CAAC-OS) material. The gate electrode 142G, the source electrode 142S and the drain electrode 142D of the OS FET device 140 can include metal material the same with the metal layers 124, but not limited to this.

Please refer to FIGS. 1 and 2 again. The gate electrode 142G is electrically connected to a word line WL, the source electrode 142S is electrically connected to a bit line BL, and the drain electrode 142D is electrically connected to the DT capacitor 110 as shown in FIG. 1. And it is noteworthy that the bit line BL is formed above the OS FET device 140 as shown in FIG. 2. More important, the bit line BL and the word line WL are formed in the BEOL interconnection structure 120 and thus can include the material the same with the metal layers 124.

According to the DOSRAM cell 100 provided by the first preferred embodiment, the DT capacitor 110 is formed in the substrate 102 before forming the active/passive device and the OS FET device 140, therefore a depth of the DT capacitor 110 is increased to several decades to several hundreds micrometers.

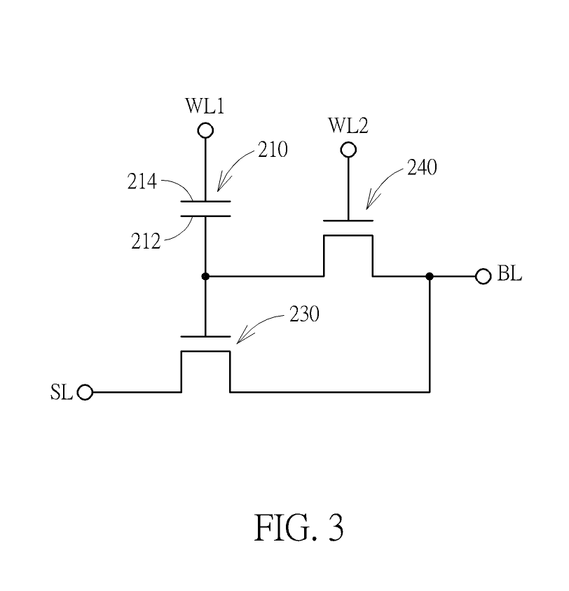

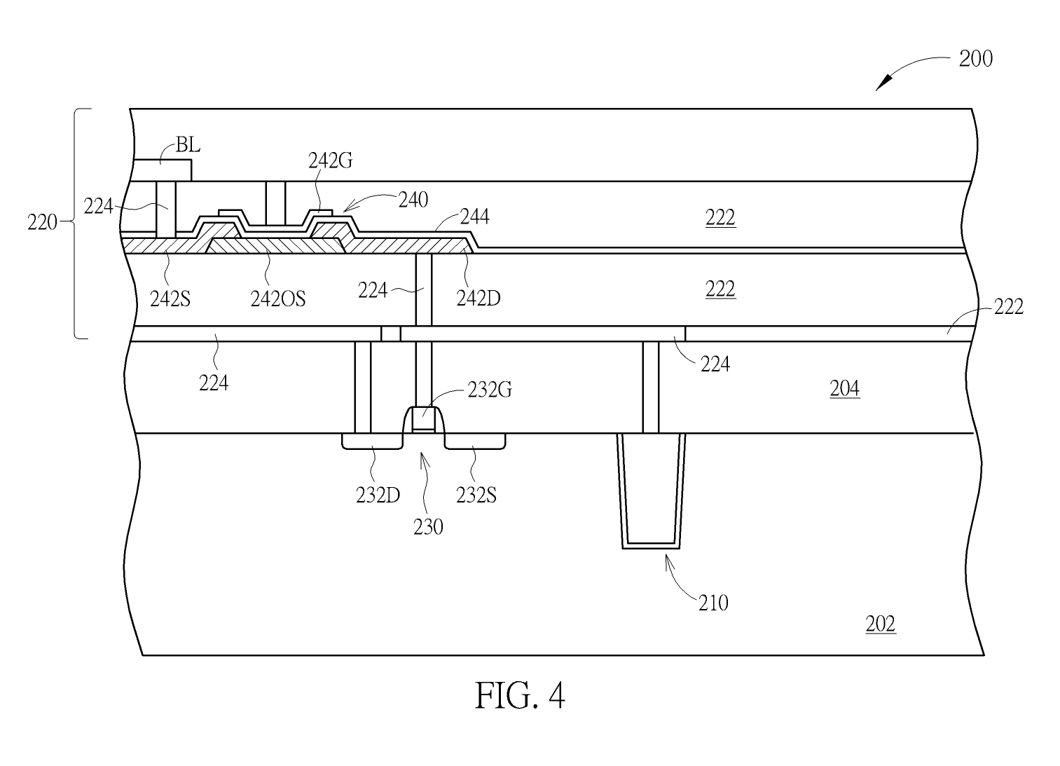

According to a second preferred embodiment of the present invention, a non-volatile oxide semiconductor random access memory (hereinafter abbreviated as NOSRAM) cell is provided. As mentioned above, since an OS FET device renders excellent electric characteristics of an extremely low off-state current, the OS FET device is integrated in the non-volatile random access memory cell. Hence the non-volatile random access memory cell with the OS FET integrated therein is referred to as a NOSRAM cell. Please refer to FIG. 3 and FIG. 4, FIG. 3 is a circuit diagram of a NOSRAM cell provided by a second preferred embodiment of the present invention and FIG. 4 is a schematic drawing illustrating the NOSRAM cell provided by the second preferred embodiment. It should be noted that elements the same in the first and second preferred embodiment can include the same material, and thus those details are omitted in the interest of brevity.

As shown in FIGS. 3 and 4. The NOSRAM cell 200 provided by the second preferred embodiment includes a substrate 202, a DT capacitor 210 formed in the substrate 202, and a metal-oxide-semiconductor field effect transistor (hereinafter abbreviated as MOS FET) device 230 formed on the substrate 202. The DT capacitor 210 of the NOSRAM 200 can be formed by steps the same with those described in the first preferred embodiment, therefore those details are omitted for simplicity. In the preferred embodiment, the DT capacitor 210 is preferably a DT MIM capacitor, but not limited to this. As shown in FIG. 3, the DT capacitor 210 includes a top electrode 212 and a bottom electrode 214. Please still refer to FIG. 4. Next, a plurality of active and/or passive devices (not shown) can be fabricated in and/or on the substrate 202 by FEOL processes. The active and/or passive devices construct integrated circuit(s) required for the memory. Device designs for the above mentioned active/passive devices and the details of the FEOL processes are familiar to a person having ordinary skill in the art, therefore those details are all omitted in the interest of brevity.

As shown in FIG. 4, the MOS FET device 230 is formed next to the DT capacitor 210, and the MOS FET device 230 includes a gate electrode 232G, a source electrode 232S and a drain electrode 232D. Thereafter, at least an insulating layer 204 such as an ILD layer 204 is formed to cover the DT capacitor 210, the MOS FET device 230, and other devices. Next, a BEOL interconnection structure 220 is formed on the substrate 202. The BEOL interconnection structure 220 interconnects the active/passive devices of the integrated circuit (s) and may provide circuit-to-circuit connections, or may establish contacts with input and output terminals. As shown in FIG. 4, the BEOL interconnection structure 220 includes a plurality of dielectric layers 222 such as interlayer dielectric layers or IMD layers and a plurality of metal layers 224 (including wires and vias) formed in the dielectric layers 222. As mentioned above, the BEOL interconnection structure 220 is formed by steps of forming one dielectric layer 222, forming recesses (not shown) in the dielectric layer 222, and filling up the recesses with metal material such as Al or Cu to form the metal layers 224. These abovementioned steps can be repeated any number of times to form the stacked structure of the BEOL interconnection structure 220. As shown in FIG. 4, the ILD layer 204 and the dielectric layer 222 all cover the DT capacitor 210 and the MOS FET device 230. More important, one of the metal layers 224 is electrically connected to the DT capacitor 210 and a gate electrode 232G of the MOS FET device 230 as shown in FIG. 4 in accordance with the preferred embodiment.

More important, the NOSRAM 200 provided by the second preferred embodiment includes an OS FET device 240 formed in BEOL interconnection structure 220. That is, the OS FET device 240 is formed on the insulating layer 204. Consequently, the MOS FET device 230 is formed in between the DT capacitor 210 and the OS FET device 240 in a substrate-thickness direction. The OS FET device 240 includes an OS layer 2420S, a gate electrode 242G, a source electrode 242S, a drain electrode 242D, and a dielectric layer 244 isolating the gate electrode 242G from the OS layer 2420S, the source electrode 242S and the drain electrode 242D. It should be noted that the MOS FET device 230 has a channel formed of silicon, it is referred to as Si transistor while the OS FET device 240 has a channel formed of OS layer, it is referred to as OS transistor.

Please refer to FIGS. 3 and 4 again. The top electrode 212 of the DT capacitor 210 is electrically connected to the OS FET device 240 and the MOS FET device 230, and the bottom electrode 214 of the DT capacitor 210 is electrically connected to a first word line WL1. Specifically, the top electrode 212 of the DT capacitor 210 is electrically connected to the gate electrode 230G of the MOS FET device 230 in parallel, and the top electrode 212 and the gate electrode 230G are electrically connected to the drain electrode 242D of the OS FET device 240 in series. The gate electrode 242G of the OS FET device 240 is electrically connected to a second word line WL2, and the source electrode 242S of the OS FET device 240 is electrically connected to a bit line BL. The source electrode 232S of the MOS FET device 230 is electrically connected to a select line SL and the drain electrode 232D of the MOS FET device 230 is electrically connected to the bit line BL (shown in FIG. 3).

According to the NOSRAM cell 200 provided by the second preferred embodiment, the DT capacitor 210 is formed in the substrate 202 before forming the MOS FET device 230 and the OS FET device 240, therefore a depth of the DT capacitor 210 is increased to several decades to several hundreds micrometers.

According to the memory cell (including the DOSRAM and the NOSRAM) provided by the present invention, the DT capacitor is always formed in the substrate before forming the MOS FET device, OS FET device and the BEOL interconnection structure. That is, the memory cell provided by the present invention includes a DT capacitor (−MOS FET)-OS FET upwardly built up scheme. According to this memory scheme, a depth of the DT capacitor is increased to several decades to several hundreds micrometers. Therefore, a higher capacitance can be achieved without increasing the memory cell size according to the present invention. Furthermore, the cell size can be further reduced and the cell density can be increased without impacting the capacitance according to the memory cell provided by the present invention. Additionally, thermal budget can be increased due to this DT capacitor (−MOS FET)-OS FET upwardly built up scheme.

Those skilled in the art will readily observe that numerous modifications and alterations of the device and method may be made while retaining the teachings of the invention. Accordingly, the above disclosure should be construed as limited only by the metes and bounds of the appended claims.

1. A memory cell comprising:
a substrate;
a deep trench (DT) capacitor formed in the substrate;
a metal-oxide-semiconductor field effect transistor (MOS FET) device formed on the substrate, the MOS FET device comprising a second drain electrode, and the second drain electrode being directly electrically connected to a bit line;
at least an insulting layer formed on the substrate; and
an oxide semiconductor field effect transistor (OS FET) device formed on the insulating layer, the OS FET device being electrically connected to the DT capacitor, the OS FET device comprising a first source electrode, and the first source electrode being directly electrically connected to the bit line.

2-8. (canceled)

9. The memory cell according to claim 1, wherein the insulating layer covers the MOS FET device and the DT capacitor.

10. The memory cell according to claim 1, wherein the MOS FET device is formed in between the DT capacitor and the OS FET device in a substrate-thickness diagonal direction.

11. The memory cell according to claim 1, wherein the DT capacitor comprises a top electrode and a bottom electrode.

12. The memory cell according to claim 11, wherein the top electrode is electrically connected to the OS FET device and the MOS FET device, and the bottom electrode is electrically connected to a first word line.

13. The memory cell according to claim 1, wherein the OS FET device further comprises a first gate electrode and a first drain electrode, and the MOS FET device further comprises a second gate electrode and a second source electrode.

14. The memory cell according to claim 13, wherein the first gate electrode is electrically connected to a second word line, and the first drain electrode is electrically connected to the DT capacitor and the second gate electrode of the MOS FET device.

15. The memory cell according to claim 13, wherein the second source electrode is electrically connected to a select line.

16-21. (canceled)
